(19) United States
(12) Patent Application Publication
(10) Pub. No.: US 2024/0241082 A1
(43) Pub. Date: Jul. 18, 2024

(54) REMOTE SENSOR ARRANGEMENT

(71) Applicant: Endress+Hauser Wetzer GmbH+Co. KG, Nesselwang (DE)

(72) Inventors: Dietmar Frühauf, Lörrach (DE); Florian Krogmann, Kreuzlingen (CH); Raphael Kuhnen, Schliengen (DE); Pavo Vrdoljak, Nesselwang (DE); Peter Klöfer, Steinen (DE); Benjamin Scherer, Oberried (DE); Sergey Lopatin, Lörrach (DE); Anh Tuan Tham, Berlin (DE); Volker Frey, Schopfheim (DE)

(21) Appl. No.: 18/562,054

(22) PCT Filed: May 11, 2022
(86) PCT No.: PCT/EP2022/062718

§ 371 Date: Nov. 17, 2023

(30) Foreign Application Priority Data
May 20, 2021 (DE) 10 2021 113 199.5

(51) Int. Cl. G01N 27/90; G01K 7/38; G01L 9/16; G01R 33/06; G01R 33/07; G01R 33/09; G01R 33/12; G01R 33/16

(52) U.S. Cl. CPC G01N 27/9006; G01K 7/38; G01L 9/16; G01R 33/063; G01R 33/07; G01R 33/093; G01R 33/1223; G01R 33/16

(57) ABSTRACT

A sensor arrangement for determining a process variable of a medium in a containment comprises a sensor apparatus, a magnetic field apparatus, and a detection apparatus. The magnetic field apparat produces a magnetic field that penetrates the sensor apparatus, the detection apparatus and partially the medium. The sensor apparatus is embodied such that a magnetic property of a component of the sensor apparatus depends on the process variable, and the magnetic field of the magnetic field apparatus is influenceable by the sensor apparatus as a function of process variable. The detection apparatus is embodied to register a variable related with the magnetic field, especially the magnetic flux density, the magnetic susceptibility or the magnetic permeability, and, based on that variable, to determine the process variable. The sensor apparatus is arranged within an internal volume of the containment and the detection apparatus is arranged outside of the containment.

In industrial process automation, the most varied of field devices are used in a wide variety of embodiments for monitoring and/or determining various process variables and/or characteristic variables of a medium. In the context of the invention, in principle, referred to as field devices are all measuring devices, which are applied near to a process and which deliver, or process, process relevant information, thus, also remote I/Os, radio adapters, and, generally, electronic components, which are arranged at the field level. A large number of such field devices are manufactured and sold by the Endress+Hauser group of companies.

Many measuring principles underpinning different field devices known in the state of the art permit characterizing a medium as regards its magnetic and/or electrical properties. In this connection, used are both invasive measuring devices, in the case of which the sensor unit is introduced in direct contact with the medium, as well as also non-invasive measuring devices, in the case of which the process variable of the medium is registered outside of the container, in which the medium is located. Non-invasive measuring devices offer basically the advantage that no encroachment into the process is necessary. However, such measuring devices have to this point in time been only limitedly available, since as regards achievable accuracy of measurement and possible disturbing influences, for example, by the container wall or the environment, many different factors need to be taken into consideration. Nevertheless, a common goal is to have the measuring device encroach as little as possible into the process.

Another goal lies in the continuing miniaturization coupled with increasing capability and expansion of the range of applications of sensors. Especially, sensors are desirable, which enable a comprehensive characterizing of a medium as regards many different process variables and/or characteristic variables of the medium. Regarding magnetic and/or electrical properties of the medium in this connection, for example, precise systems are required for registering changes of magnetic and/or electrical fields and, depending on sensor type, in given cases, also gravitational fields.

Starting from these considerations, an object of the invention is to provide a sensor for characterizing media, especially in industrial process automation, by means of which highly precise measurements are possible with minimal encroachment into the process.

This object is achieved according to the invention by a sensor arrangement for determining and/or monitoring a process variable and/or characteristic variable of a medium in a containment, comprising
a sensor apparatus,
a magnetic field apparatus, and
a detection apparatus.

The magnetic field apparatus serves for producing a magnetic field in such a manner that the magnetic field penetrates at least the sensor apparatus, the detection apparatus and partially the medium. The sensor apparatus is, in turn, embodied and/or arranged in such a manner that at least one magnetic property of a component of the sensor apparatus depends on the process variable and/or characteristic variable and the magnetic field of the magnetic field apparatus is influenceable by means of the sensor apparatus as a function of the process variable and/or characteristic variable. The detection apparatus is embodied to register a variable related with the magnetic field, especially the magnetic flux density, the magnetic susceptibility or the magnetic permeability, and, based on the variable related with the magnetic field, to determine and/or to monitor the process variable and/or characteristic variable. In such case, the sensor apparatus is arranged within an internal volume of the containment and the detection apparatus is arranged outside of the containment.

The sensor arrangement of the invention is, thus, embodied in such a manner that a minimum encroachment into the process occurs. An interaction with the medium occurs only by means of the sensor apparatus, which is arranged in an internal volume of the containment and, thus, is in contact with the medium. The detection apparatus is, in contrast, arranged outside of the containment. Also the magnetic field apparatus can be arranged outside of the containment. Advantageously, an opening in a wall of the containment is not required.

The sensor apparatus can have one or more components, for which at least one magnetic property is dependent on the process variable and/or characteristic variable. In such case, different components can be equally or differently embodied, especially be made of the same or different materials. Combinations of various components are advantageous, especially as regards suppressing disturbing external magnetic fields or as regards desired expansion of the range of application of a sensor arrangement.

The sensor apparatus can, additionally, be secured on an inner surface of the containment, for example, a containment in the form of a container or a pipeline. In such case, both a releasable as well as also a non-releasable, especially material bonded, securement can be used, especially with application of the suitable securement means. The sensor apparatus can, however, also be introduced into the internal volume of the containment, without securing the same to a wall. In such case, the sensor apparatus floats in the medium. Also an integration of the sensor apparatus into the wall of the containment is an option, especially in such a manner that the sensor apparatus is flush with the inner surface of the containment.

The detection apparatus can, on the one hand, be secured on an outer surface of the containment or be arranged spaced therefrom. Especially, the detection apparatus can also be part of a separate unit, which can be brought into the vicinity of the containment for registering the process variable and/or characteristic variable of the medium.

The containment is, for example, a container or a pipeline. It can likewise be a single use-container. Single use process solutions, or single use technologies, are used in increasing measure in many industrial processes, especially in pharmaceutical, biological, biochemical and biotechnological processes. Corresponding process plants comprise pipelines or reactors, which are embodied as single use containers (also referred to as disposables, or disposable bioreactors or single-use bioreactors, or single-use components). Such single use containers can be, for example, flexible containers, e.g. bags, hoses or fermenters. Many single use containers, e.g. bioreactors or fermenters, have supply and drain lines, which can be embodied as hoses, or in which also rigid tubular pieces can be inserted as supply and drain lines. An advantage of single-use technology is that after terminating a process the single use container is discarded. In this way, complex cleaning- and sterilization methods are avoided. Especially, by using single use containers, the risk of cross contaminations is avoided and therewith process safety increased. On the other hand, sensors in the field of single-use technology must meet special requirements, for example, passageways to the environment, especially unsealed locations, must be avoided. Thus, it is, indeed, also usual to bring the sensors into the single use container (invasive sensors), which makes the coupling to the medium especially easy to implement, while, however, sensors secured externally on the container (non-invasive sensors) have the advantage that no connection to the process is necessary and the sensors can, in given cases, be used over and over again and the requirements for sterility can be significantly more easily fulfilled. In the present solution only the sensor apparatus needs to be introduced into the containment. The other components can remain outside of the containment and be therewith advantageously reusable. Additionally, a connection from the internal volume of the container to the environment is not necessary, so that no unsealed sites of the containment can arise.

In an embodiment, the magnetic field apparatus comprises at least one coil and/or one permanent magnet. Additionally, also a coil core can be present, especially a material having a high permeability. It is, on the one hand, possible to apply an essentially constant magnetic field. It is, however, likewise possible to modulate the magnetic field, especially as regards frequency and/or amplitude. Such modulation is especially advantageous for reducing the influence of disturbance signals.

An embodiment of the sensor arrangement includes that a component of the sensor apparatus comprises a ferromagnetic material. The ferromagnetic material has at a predeterminable phase transformation temperature a phase change from a paramagnetic state to a ferromagnetic state.

The ferromagnetic state is characterized by the tendency to have a parallel orientation of the magnetic moments of the atoms of the material.

The ferromagnetic material is, for example, cobalt, iron, or nickel or one of their alloys. Especially, it can also be a nanocrystalline or amorphous material.

An alternative embodiment of the sensor arrangement includes that a component of the sensor apparatus comprises a magnetostrictive material. A magnetostrictive material is distinguished by a deformation of the material as a result of an applied magnetic field. In this connection, one distinguishes between Joule magnetostriction, in the case of which a length change occurs as a result of a change of the magnetization, the Villary effect, which is also referred to as the inverse magnetostrictive effect, in the case of which, thus, a change of the mechanical stress causes a change of the magnetization, and the Delta-E effect, which describes a change of the modulus of elasticity as a result of a change of the magnetization.

The magnetostrictive material is, for example, nickel or an iron alloy, especially an alloy of cobalt and iron, an alloy of gallium and iron, e.g. Galfenol, or an alloy of terbium, dysprosium and iron, e.g. Terfenol. Preferably, a material with best possible permeability is selected, in order to maximize a penetration of the sensor apparatus by the magnetic field. Both solid magnetostrictive components can be used as well as also those, which are of a porous material. In the case of a porous material, especially also a mechanical deformation of the porous material can be utilized for registering the particular process variable and/or characteristic variable.

In additional, alternative embodiments, the component of the sensor apparatus comprises a ferrite material, or a permanent magnet, whose magnetic field depends on the process variable, for example, the temperature of the medium.

It is relative to the sensor apparatus advantageous that such includes a support or a membrane, on which the component of the sensor apparatus, especially the ferromagnetic or magnetostrictive material, is applied, for example, by means of material bonded connection, for example, in the form of a layer or an elongated element. Especially, the component can be joined with the support or membrane. By means of the support or membrane, in such case, for example, a securement to an interior surface of the containment can occur.

The support or the membrane is produced preferably of a non-magnetic material, for example, stainless steel, brass, or aluminum.

It is, additionally, advantageous that the component, which for this embodiment preferably comprises a magnetostrictive material, be applied on the support or membrane in such a manner that a predeterminable, mechanical base stress is present between the component and the support or membrane. In this way, a linearizing of a sensor characteristic, or sensor behavior, can be realized.

In the case, in which the component of the sensor apparatus comprises a magnetostrictive material, which is applied on the support or membrane, it is, additionally, advantageous that the support or membrane and the magnetostrictive material have different coefficients of thermal expansion. This embodiment is suited especially for registering temperature of the medium. As a result, after a change of temperature of the medium, there arises, due to the different coefficients of thermal expansion of the support or membrane and the magnetostrictive material, a mechanical stress in the magnetostrictive material and, associated therewith, a change of the magnetization, which, in turn, influences the applied magnetic field. It is, thus, possible, based on the magnetic field, to ascertain temperature of the medium, by using the Villary effect.

A sensor apparatus having a support or a membrane is suited, however, also for determining other process variables and/or characteristic variables of the medium, such as, for example, the pressure of the medium in the containment.

Another embodiment of the sensor apparatus includes that the component, whose at least one magnetic property is dependent on the process variable and/or characteristic variable, is arranged in a housing. For example, the housing can be an encapsulation excluding the medium, especially an encapsulation of a non-magnetic material, e.g. a stainless steel. In this way, for example, a compatibility for the particular medium can be achieved. Such an embodiment, is, additionally, advantageous in the case of a sensor apparatus floating in the medium.

In an embodiment of the sensor arrangement, the detection apparatus comprises a magnetic field sensor. The magnetic field sensor serves for detecting the magnetic field outside of the containment, as influenced by the sensor apparatus in the interior of the containment as a function of process variable and/or characteristic variable of the medium, and/or for ascertaining the variable functionally related with the magnetic field. For instance, the detection apparatus can also include a computer unit, which is embodied to ascertain the process variable and/or characteristic variable of the medium based on the variable functionally related with the magnetic field.

The magnetic field sensor is in an embodiment a Hall sensor or a GMR sensor.

In an alternative embodiment, the magnetic field sensor is a quantum sensor. Quantum sensors, in the case of which the most varied of quantum effects are utilized for determining various physical and/or chemical, measured variables, concern various newer developments in the field of sensor systems. In connection with industrial process automation, such approaches are especially of interest regarding an increasing striving for miniaturization coupled with increasing the capabilities, especially the measuring accuracy, of sensors.

Quantum sensors operate based on the fact that certain quantum states of individual atoms or arrangements of atoms can be very exactly controlled and read-out. In this way, for example, precise and low-disturbance measurements of electrical and/or magnetic fields as well as gravitation fields are possible with resolutions in the nanometer range. In this connection, various spin based sensor arrangements have become known, in which atomic transitions in crystal bodies are applied for detecting changes of movements, electrical and/or magnetic fields or even gravitation fields. Moreover, also various systems based on quantum optical effects have become known, such as, for example, quantum gravimeters, NMR gyroscopes and optically pumped magnetometers, wherein especially the latter, among others, operate based on gas cells.

Thus, an embodiment of the magnetic field sensor in the form of a quantum sensor includes that the magnetic field sensor involves a gas cell. In the case of a quantum sensor in the form of a gas cell, atomic transitions as well as spin states, among others, are optically detected for determining magnetic and/electrical properties. A gas cell typically comprises a gaseous alkali metal as well as a buffer gas. Magnetic properties of a medium surrounding the gas cell can be determined by means Rydberg states produced in the gas cell.

Gas cells are applied often in quantum based standards, which register physical variables with high precision, for example, in frequency standards, or atomic clocks, such as known from EP 0 550 240 B1. In U.S. Pat. No. 10,184,796 B2, moreover, an atomic gyroscope in chip size is described, in the case of which a gas cell is used for determining the magnetic field. An optically pumped magnetometer based on a gas cell is known from U.S. Pat. No. 9,329,152 B2. By manipulating the atomic states in gas cells, other application fields of gas cells can be accessed. Thus, JP 4066804 A2 describes use of gas cells for determining absolute path lengths. Moreover, gas cells are also applied as starting point for microwave sources, such as described in EP 1 224 709 B1.

An alternative embodiment of the magnetic field sensor in the form of a quantum sensor includes that the magnetic field sensor is a sensor comprising at least one crystal body having at least one defect. In the case of such spin based quantum sensors, atomic transitions in various crystal bodies are utilized, in order to detect small changes of movements, electrical and/or magnetic fields or gravitation fields. Typically used as crystal body is diamond having at least one silicon- or nitrogen defect, silicon carbide having at least one silicon defect or hexagonal boron nitride having at least one defect in the form of a color center. The crystal body can basically have one or more defects. In the case of a plurality of defects, a linear arrangement of the defects is preferable.

In this connection, known from DE 3742878 A1, for example, is an optical magnetic field sensor, in the case of which a crystal is used as magnetically sensitive optical component. Known from DE 10 2017 205 099 A1 is a sensor apparatus having a crystal body having at least one defect, a light source, a high frequency system for loading the crystal body with a high frequency signal, and a detection unit for detecting a magnetic field dependent fluorescent signal. Other sensors using defects in crystal bodies are described in DE 10 2017 205 265 A1, DE 10 2014 219 550 A1, DE 10 2018 214 617 A1, and DE 10 2016 210 259 A1.

Additionally known from the German patent application No. 10 2020 123 993.9, unpublished as of the earliest filing date of this application, is a sensor apparatus, which determines a process variable of a medium based on a fluorescent signal of a crystal body having at least one defect and in the case of which additionally a state monitoring of the process is performed based on a variable characteristic for the magnetic field. Known from German patent application No. 10 2021 100223.0 likewise unpublished as of the earliest filing date of this application is, moreover, a limit fill level sensor, in the case of which information concerning a limit level is ascertained based on the fluorescence.

Regarding the detection apparatus having a quantum sensor having a crystal body having at least one defect, advantageously the detection apparatus additionally comprises an excitation unit for optical exciting of the defect, an apparatus for detecting a magnetic field dependent, fluorescent signal from the crystal body and an evaluation unit for determining the variable related with the magnetic field based on the fluorescent signal.

The excitation unit for optical exciting of the defect can be, for example, a laser or a light emitting diode (LED). The detector can, in turn, be, for example, a photodetector or a CMOS sensor. Additionally, the detection unit can use other optical elements, such as, for example, various filters, lenses and/or mirrors. The excitation unit and the detector can, on the one hand, be arranged in the region of the crystal body, or be spatially separated from the crystal body. In the second case, optical fibers can be present for conducting the excitation light and the fluorescent signal.

Additionally, the detection apparatus can have a unit for exciting high frequency- or microwave radiation. This enables the exciting of electrons to higher energy levels.

Also as regards the evaluation unit for determining the variable related with the magnetic field based on the fluorescent signal, different variants are possible. For example, the evaluation unit can comprise a lock-in amplifier and a modulator, by means of which, for example, the magnetic field can be modulated. This enables an evaluation of the fluorescent signal based on frequency and, associated therewith, an evaluation realizable in simple manner, especially with reduced influence of disturbance signals.

In an embodiment of the sensor arrangement, the process variable is the temperature of the medium. Regarding the temperature, advantageously only the sensor apparatus is arranged within the containment. The sensor apparatus has, thus, always a good thermal contact with the medium. Additionally, no openings or windows are required within the containment for registering a temperature dependent measurement signal. The registering of the temperature occurs contactlessly based on the magnetic field influenced by the sensor apparatus. Advantageously for such a thermometer, no heat conduction, or heat flows, from or to the environment need to be taken into consideration for determining the temperature. Likewise, there is no undesired energy inflow from the environment into the containment.

In connection with determining the temperature, it is in an embodiment an option that the component of the sensor apparatus comprises a ferromagnetic material. Typically, the phase change from the paramagnetic to the ferromagnetic state or vice versa, occurs not abrupty at the phase transformation temperature, but, instead, continuously within a phase change temperature interval around the Curie temperature and characteristic for the particular material. Within the phase change temperature interval, a highly precise temperature determination can be performed, since a change of temperature leads to a comparatively large change of the magnetization, which, in this case, is taken into consideration as the variable related with the magnetic field.

In the case, in which the component of the sensor apparatus comprises, in contrast, a magnetostrictive material, in turn, an embodiment is advantageous, in the case of which different coefficients of thermal expansion of the magnetostrictive material and an element, which is connected fixedly with the magnetostrictive material, are utilized, such as, for example, in the case of use of a support or a membrane.

As regards the determining of the temperature of the medium, it is, additionally, advantageous that, when the variable related with the magnetic field is the magnetic flux density, the temperature is determined based on, or with the aid of, the gyromagnetic ratio and the magnetic flux density. The gyromagnetic ratio is defined as proportionality factor between the spin of a particle and the magnetic moment and is itself not influenced by the temperature. Influenced rather is the product of the gyromagnetic ratio and the magnetic flux density. An influence of the temperature comes accordingly exclusively from the sensor apparatus influencing the magnetic field, such that an evaluation of the magnetic field as regards the temperature is possible uniquely with the help of the gyromagnetic ratio. This leads to an especially high accuracy of measurement.

In an additional embodiment of the sensor arrangement, the process variable is the pressure of the medium. Upon change of the pressure within the containment in the case of a sensor arrangement having a magnetostrictive component, for example, a mechanical stress and/or deformation in the magnetostrictive material in contact with the medium arises, and, associated therewith, a change of the magnetization, or of the magnetic field, which can be used for ascertaining the pressure. Also, in such case, the Villary effect is taken into consideration for registering the pressure.

In the case, in which a sensor arrangement serves for registering the pressure of a medium, also an embodiment of the sensor apparatus in the form of a ceramic pressure measuring cell known per se in the state of the art is an option, to which a magnetostrictive material, for example, in the form of a thin layer, is applied. In such case, a pressure change leads to a deflection of a diaphragm of the ceramic pressure measuring cell, and, associated therewith, to a stress of the magnetostrictive material as a result of the deformation.

Another embodiment of the sensor arrangement includes, finally, that the sensor arrangement, especially the detection apparatus, is embodied to register an influence of a wall of the containment on the magnetic field, especially based on a thickness of the wall and/or based on the material, of which the containment is produced, and the detection apparatus is embodied to take into consideration the influence of the wall of the containment when determining and/or monitoring the process variable and/or characteristic variable. In this way, influences of different materials and different thicknesses of different containments on the magnetic field, leading especially to an attenuation of the magnetic field in the interior of the containment dependent on the containment, can be taken into consideration, this in turn likewise resulting in an increased accuracy of measurement.

In summary, the invention enables the registering of a process variable and/or characteristic variable of a medium through a wall of a containment, in which the medium is located. No openings or windows are required in the containment for this. The invention is based on the recognition that the magnetic field, which is influenced by the process variable and/or characteristic variable of the medium by means of a suitable sensor arrangement, is registrable outwardly of the containment, i.e. through the wall of the containment.

The invention accordingly provides for a sensor a highly powerful, simple and robust construction, which is especially advantageous, particularly low-maintenance. Thus with the sensor arrangement of the invention, the encroachment in the process required for installation of the same can be advantageously minimized, since only the sensor apparatus needs to be introduced into an internal volume of the containment. Also use of the sensor arrangement in an explosion endangered atmosphere is directly possible and, especially, without the necessity of auxiliary energy.

The invention as well as its advantageous embodiments will now be explained in greater detail. The figures of the drawing show as follows:

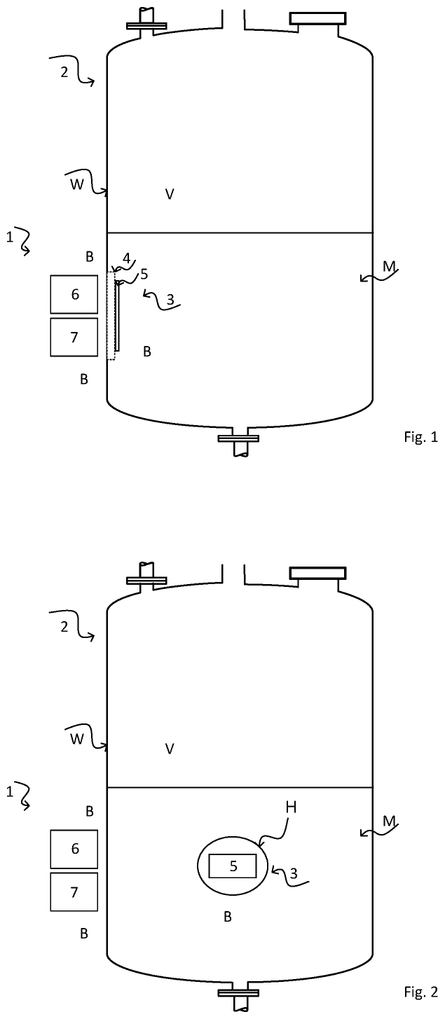

FIG. 1 a sensor arrangement of the invention with a sensor apparatus secured on a container wall;

FIG. 2 a sensor arrangement of the invention having a sensor apparatus arranged floating in a medium;

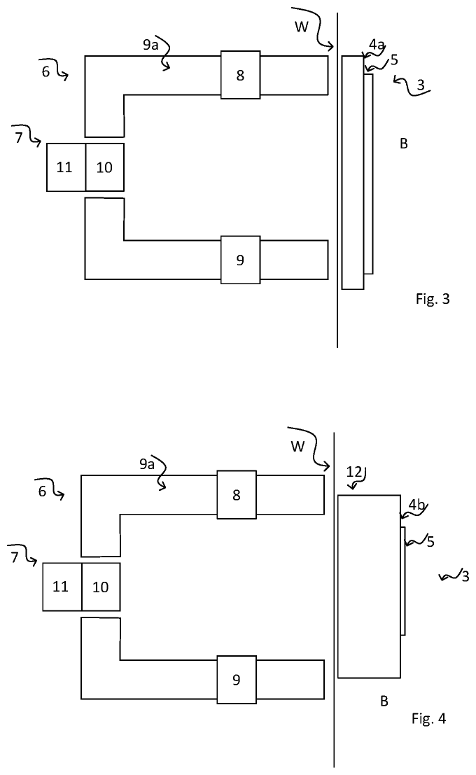

FIG. 3 a sensor arrangement of the invention for determining the temperature of a medium;

FIG. 4 a sensor arrangement of the invention for determining pressure of a medium;

FIG. 5 a simplified energy diagram for a negatively charged NV center in diamond, and

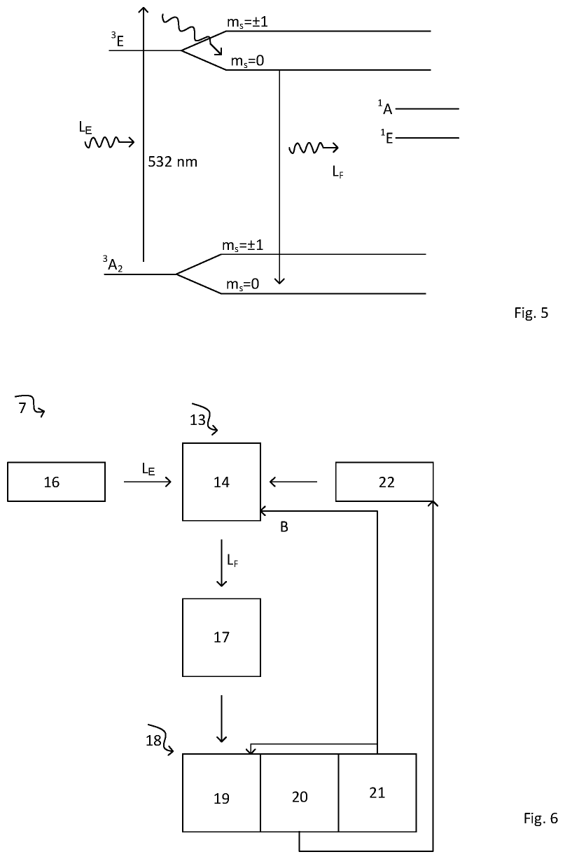

FIG. 6 a schematic arrangement of a detection apparatus for a quantum sensor having a crystal body having at least one defect.

In the figures, equal elements are provided with equal reference characters.

FIG. 1 shows a first, schematic embodiment for a sensor arrangement 1 of the invention for determining and/or monitoring a process variable and/or characteristic variable of a medium M in a containment 2. The sensor apparatus 3 is arranged within the internal volume V of the containment 2 (here in the form of a container) and secured on the inner surface of the wall W of the containment 2. Sensor apparatus 3 includes a component 5, for which at least one magnetic property depends on the process variable and/or characteristic variable of the medium M and which in the present case is embodied in the form of a thin, elongated element. For example, this component 5 can be an element made of a ferromagnetic or magnetostrictive material. Here, the component 5 is arranged on a support or membrane 4. Such is, however, not absolutely required, because of which the support or membrane is shown dashed.

Sensor arrangement 1 further includes a magnetic field apparatus 6 for producing a magnetic field B in the region of the sensor apparatus 3, in at least one part of the medium M and in the region of the detection apparatus 7. Magnetic field B thus penetrates the detection apparatus 7, the sensor apparatus 3 and the medium. The magnetic field B is, additionally, influenced by the sensor apparatus 3, thus by the component 5, such that, based on the magnetic field B registered, or detected, by the detection apparatus 7, or based on a registered, or detected, variable related with the magnetic field B, the process variable and/or characteristic variable of the medium M can be determined and/or monitored. According to the invention, the detection apparatus 7 and in the illustrated example also the magnetic field apparatus 6 are arranged outside of the containment 2.

Another embodiment of a sensor arrangement 1 of the invention is shown in FIG. 2. In contrast with the embodiment of FIG. 1, the sensor apparatus 3 is arranged in a housing H, here a spherically shaped housing and floats in the medium. For such an arrangement, it is advantageous to provide a reference, in order to take into consideration the separation dependence of the magnetic field B and the variable separation between the sensor apparatus 3 and the detection apparatus 7 resulting for a floating embodiment of the sensor apparatus 3. In such case, the reference can be a system to execute a reference measurement or a reference curve or a suitable reference algorithm. The magnetic field has a locational dependence, which in the case of a floating sensor apparatus, can be taken into consideration using the reference.

Advantageously, the sensor arrangement 1, especially the detection apparatus 7, is embodied to ascertain an influence of the wall W of the containment on the registered magnetic field B, especially based on a thickness of the wall and/or based on the material, of which the containment 2 is made, and to take such into consideration when determining and/or monitoring the process variable and/or characteristic variable. For this, for example, suitable reference curves or formulas, for example, for different materials of the containments 2, can be stored in the detection apparatus 7, especially in a computer unit of the detection apparatus 7.

FIG. 3 shows a sensor arrangement 1 of the invention serving for registering temperature T of the medium. Sensor apparatus 3 includes, applied on a support 4a, a magnetostrictive material 5, which applied in the form of a layer on the support 4a, which is secured on the inner surface of the wall W of the container. Support 4a and magnetostrictive material 5 have different coefficients of thermal expansion, such that, as a result of a temperature change of the medium, there arises in the sensor apparatus 3 a mechanical stress, which, in turn, results in a changed magnetization of the magnetostrictive material 5 and, associated therewith, a change of the magnetic field B.

The magnetic field apparatus 6 comprises here, by way of example, a permanent magnet 8 and a coil 9 having a core 9a composed of two L shaped elements. In a gap between the two elements of the core 9a is arranged the detection apparatus 7, which comprises a magnetic field sensor 10 and a computer unit 11. The magnetic field sensor 10 can be, for example, a Hall sensor, a GMR sensor or a quantum sensor. The temperature T of the medium can be ascertained, for example, in the computer unit based on the gyromagnetic ratio as the variable related with the magnetic field B.

Another opportunity for temperature determination with a sensor arrangement of the invention results from use of a ferromagnetic material as component 5 of the sensor apparatus 3, in the case of which at least one magnetic property depends on the process variable and/or characteristic variable of the medium M, thus, the temperature T. Sensor arrangement 1 can for this second case be constructed analogously to the embodiment shown in FIG. 3.

The sensor arrangement of the invention can, however, also be used for determining other process variables and/or characteristic variables of the medium M, such as, by way of example, for the case of determining the pressure p of the medium, as shown in FIG. 4. While the magnetic field system 6 and the detection unit 7 are embodied as for the variant shown in FIG. 3, used as sensor apparatus 3 is a ceramic pressure measuring cell 12 having a diaphragm 4b, on which a magnetostrictive layer 5 is arranged.

Especially advantageous embodiments of the sensor arrangement concern detection apparatuses 7, in the case of which magnetic field sensors 8 in the form of a quantum sensor 12 are used. Quantum sensors are distinguished by being very compact coupled with being very capable and precise. The application of magnetic field sensors 8 in the form of quantum sensors 12 will now be explained, by way of example, based on a quantum sensor 12 in the form of a sensor 14 comprising at least one crystal body 15 having at least one defect.

FIG. 5 shows a simplified energy diagram for a negatively charged NV center in diamond, in order, by way of example, to explain the exciting of the defect and the detecting of the fluorescence. The following considerations hold equally for other crystal bodies with corresponding defects.

In diamond, typically each carbon atom is connected covalently with four other carbon atoms. A nitrogen vacancy center (NV center) is a defect in the diamond lattice, thus, an unoccupied lattice site and a nitrogen atom as one of the four neighboring atoms. Especially, the negatively charged NV⁻ centers are important for exciting and evaluating fluorescent signals. In the energy diagram of a negatively charged NV center, besides a triplet ground state ³A, there is an excited triplet state ³E. Each of these has three magnetic substates mₛ=0,±1. Furthermore, two metastable singlet states ¹A and¹E are located between the ground state ³A and the excited state ³E.

Using excitation light L_{E} of the green region of the visible spectrum, thus, e.g. an excitation light L_{E} with a wavelength of about 532 nm, an excitation of an electron from the ground state ³A into a vibration state of the excited ³E state takes place, after which the electron then falls back into the ground state ³A with emission of a fluorescence photon L_{F} having a wavelength of 630 nm. An applied magnetic field having a magnetic field density B leads to a splitting (Zeeman splitting) of the magnetic substates, such that the ground state is composed of three energetically separated substates, from which, in each case, an excitation can occur. The intensity of the fluorescent signal L_{F}, however, depends on the particular magnetic substate, from which the electron was excited, such that, based on the separation of the florescence minima, for example, the magnetic field density B can be calculated with the help of the Zeeman formula.

There are, however, other possible evaluations of the fluorescent signal possible, such as, for example, evaluation of the intensity of the fluorescent light, which is related with the applied magnetic field, or an electrical evaluation, for example, via a Photocurrent Detection of Magnetic Resonance (PNMR), which likewise fall within the scope of the invention.

A detection apparatus 7 by way of example for use with such a quantum sensor 13 in the form of a sensor 14 having a crystal body 15 having a defect is shown finally in FIG. 6. The detection apparatus 7 includes an excitation unit 16 for producing the excitation light L_{E} and an apparatus 17 for detecting the magnetic field dependent fluorescent signal L_{F} from the crystal body 15. Moreover, the detection apparatus 7 includes an evaluation unit 18 for determining the variable related with the magnetic field B based on the fluorescent signal L_{F}.

Additionally present for the embodiment shown in FIG. 6 is a unit 22 for exciting high frequency- or microwave radiation. Also, the evaluation unit 18 includes besides a lock-in amplifier 19 a control/computer unit 20 and a modulator 21 for modulating the magnetic field of the magnetic field apparatus.

### LIST OF REFERENCE CHARACTERS

1 sensor arrangement
2 containment
3 sensor apparatus
4 support (4a) or membrane (4b)
5 component, in the case of which a magnetic property depends on the process variable and/or characteristic variable of the medium
6 magnetic field apparatus
7 detection apparatus
8 permanent magnet
9 coil, 9a core
10 magnetic field sensor
11 computer unit
12 ceramic pressure measuring cell
13 quantum sensor
14 sensor comprising a crystal having a defect
15 crystal
16 excitation unit
17 unit for detecting the fluorescent signal
18 evaluation unit
19 lock-In amplifier
20 control/computer unit
21 modulator
22 unit for producing high frequency- or microwave radiation
M medium
W wall
B magnetic field
V internal volume
H housing
L_{E} excitation light
L_{F} fluorescent light

1-15. (canceled)

16. A sensor arrangement for determining and/or monitoring a process variable and/or a characteristic variable of a medium in a containment, comprising:
a sensor apparatus;
a magnetic field apparatus; and
a detection apparatus,
wherein the magnetic field apparatus serves for producing a magnetic field in such a manner that the magnetic field penetrates at least the sensor apparatus, the detection apparatus, and partially the medium,
wherein the sensor apparatus is embodied and/or arranged in such a manner that at least one magnetic property of a component of the sensor apparatus depends on the process variable and/or the characteristic variable and that the magnetic field of the magnetic field apparatus is influenceable by the sensor apparatus as a function of the process variable and/or the characteristic variable,
wherein the detection apparatus is embodied to register a variable related with the magnetic field, and, based on the variable related with the magnetic field, to determine and/or to monitor the process variable and/or the characteristic variable, and
wherein the sensor apparatus is arranged within an internal volume of the containment and the detection apparatus is arranged outside of the containment.

17. The sensor arrangement of claim 16,
wherein the variable related with the magnetic field is: a magnetic flux density; a magnetic susceptibility; or a magnetic permeability.

18. The sensor arrangement as claimed in claim 16,
wherein the magnetic field apparatus includes at least one coil and/or one permanent magnet.

19. The sensor arrangement as claimed in claim 16,
wherein the component of the sensor apparatus includes a ferromagnetic material.

20. The sensor arrangement as claimed in claim 16,
wherein the component of the sensor apparatus includes a magnetostrictive material.

21. The sensor arrangement as claimed in claim 20,
wherein the sensor apparatus includes a support or a membrane on which the component of the sensor apparatus is applied.

22. The sensor arrangement as claimed in claim 21,
wherein the magnetostrictive material is applied on the support or the membrane, and wherein the support or the membrane (4b) and the magnetostrictive material have different coefficients of thermal expansion.

23. The sensor arrangement as claimed in claim 16,
wherein the detection apparatus includes a magnetic field sensor.

24. The sensor arrangement as claimed in claim 23,
wherein the magnetic field sensor is a Hall sensor or a GMR sensor.

25. The sensor arrangement as claimed in claim 23,
wherein the magnetic field sensor is a quantum sensor.

26. The sensor arrangement as claimed in claim 25,
wherein the quantum sensor is a gas cell.

27. The sensor arrangement as claimed in claim 25,
wherein the quantum sensor is a sensor including at least one crystal body having at least one defect.

28. The sensor arrangement as claimed in claim 27,
wherein the detection apparatus additionally includes an excitation unit for optically exciting of the at least one defect, an apparatus for detecting a magnetic-field-dependent fluorescent signal from the at least one crystal body, and an evaluation unit for determining the variable related with the magnetic field based on the fluorescent signal.

29. The sensor arrangement as claimed in claim 16,
wherein the process variable is a temperature of the medium.

30. The sensor arrangement as claimed in claim 29,
wherein the variable related with the magnetic field is a magnetic flux density, and wherein the temperature is determined based on a gyromagnetic ratio and the magnetic flux density.

31. The sensor arrangement as claimed in claim 16,
wherein the process variable is a pressure of the medium.
